(19) United States
(12) Patent Application Publication
(10) Pub. No.: US 2017/0202084 A1
(43) Pub. Date: Jul. 13, 2017

(54) TOLERANCE COMPENSATING CIRCUIT BOARD LEVER

(71) Applicant: Hamilton Sundstrand Corporation, Charlotte, NC (US)

(72) Inventors: Jeffrey T. Wavering, Rockford, IL (US); Randy P. Gauvin, Beloit, WI (US)

(21) Appl. No.: 14/992,151

(22) Filed: Jan. 11, 2016

(51) Int. Cl. H05K 1/14; H05K 5/02

(52) U.S. Cl. CPC H05K 1/141; H05K 5/0221

(57) ABSTRACT

A control module comprises a motherboard and at least one circuit board removably connected to the motherboard. There is at least one lever connected to the removable circuit board. The lever is moveable between a release and locked position. The lever contacts a bracket in the locked position to move the bracket against a spring force, such that a bias force maintains the at least one circuit board in contact with the motherboard. A circuit board and a chassis are also discussed.

### BACKGROUND OF THE INVENTION

This application relates to a structure and method for mounting circuit boards into a motherboard.

Modern systems are becoming more and more complex. Thus, complicated controls are incorporated into many systems. As an example, one such system could be on aerospace systems such as an aircraft.

A control module for such a system may include a chassis mounting a motherboard and a plurality of removable circuit boards. One type of circuit board, known as line removal modules, may provide a variety of functions.

Designers of the control modules will mount a motherboard and then select appropriate LRMs to provide the particular function demanded by the system which will utilize the control module. It is known that the removable LRMs must be held against the motherboard such that electronic connections are made.

In the past, levers have been utilized to lock the LRMs into the chassis and in contact with the motherboard. However, due to manufacturing tolerances, the known systems do not always provide sufficient LRM travel to ensure a reliable electrical connection. Also, various biasing arrangements have been proposed but are generally complex.

### SUMMARY OF THE INVENTION

A control module comprises a motherboard and at least one circuit board removably connected to the motherboard. There is at least one lever connected to the removable circuit board. The lever is moveable between a release and locked position. The lever contacts a bracket in the locked position to move the bracket against a spring force, such that a bias force maintains the at least one circuit board in contact with the motherboard.

A circuit board and chassis are also disclosed.

These and other features may be best understood from the following drawings and specification.

### BRIEF DESCRIPTION OF THE DRAWINGS

FIG. 1A shows a control module.

FIG. 1B schematically shows connection in the FIG. 1A module.

FIG. 2 shows a locking assembly in an unlocked position.

FIG. 3A shows a locking assembly in a locked position.

FIG. 3B shows a detail.

FIG. 4 shows geometric details of the locking system.

### DETAILED DESCRIPTION

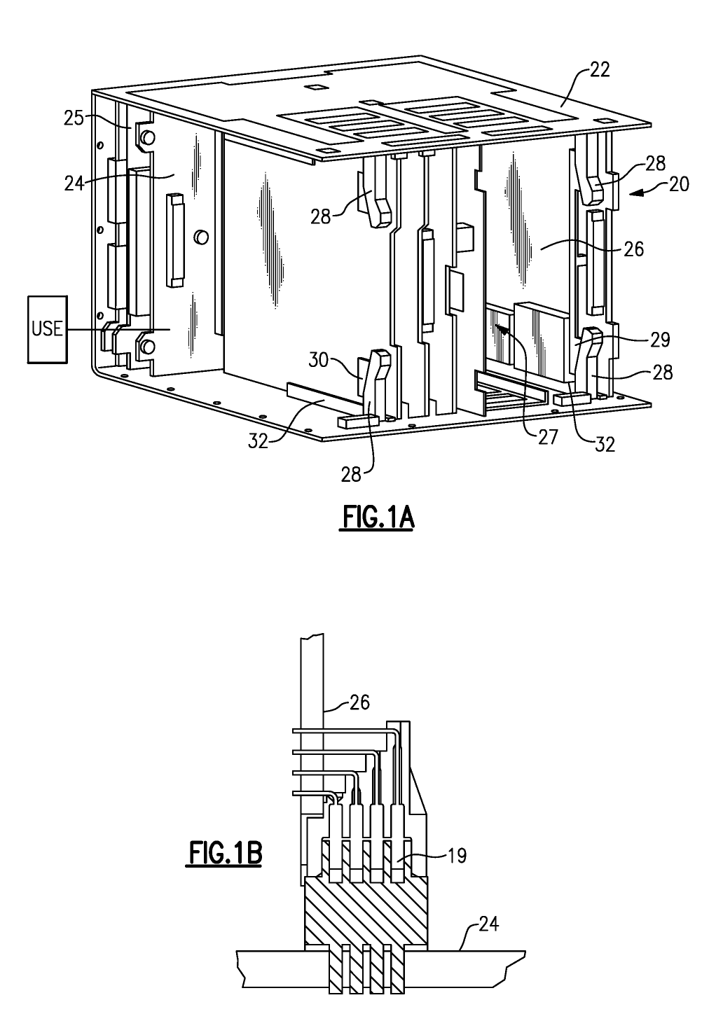

A control module 20 is illustrated in FIG. 1A. The control module may have applications such as to provide controls for a system on an aircraft. An outer chassis 22 provides a housing that mounts a motherboard 24. The motherboard 24 is at an inner end 25, and the circuit boards extend towards an opening 27 from the motherboard 24. A plurality of line replaceable modules (LRMs) 26 are shown mounted to the motherboard. Any type of circuit board may be attached to the motherboard 24.

Motherboard 24 is shown communicating with a use, which may be an aircraft system. As known, module 20 provides control functions to the use. For example, the modules may be power distribution modules, power supply modules, communications modules, etc.

Levers 28 are used at opposed ends of the LRMs 26 remote from the motherboard 24. The levers 28 lock the LRMs within the chassis 22 and engaged to the motherboard 24. The LRMs 26 are generally planar and levers 28 are at both ends of the plane. A bracket 30 is fixed on a side of the LRMs 26 and the levers 28 are pivotally mounted on the brackets 30. A channel 32, attached to the chassis 22 is used to guide the LRM's into place within chassis 22 and to align LRM's 26 to their appropriate connector on motherboard 24.

As shown in FIG. 1B, schematically, a motherboard 24 receives an electrical connection 19 from an LRM 26. Due to tolerance build-up, in the art, this connection has not always been fully mated to ensure a reliable electrical interface. A worker of ordinary skill would be able to calculate the tolerance build-up in any particular system.

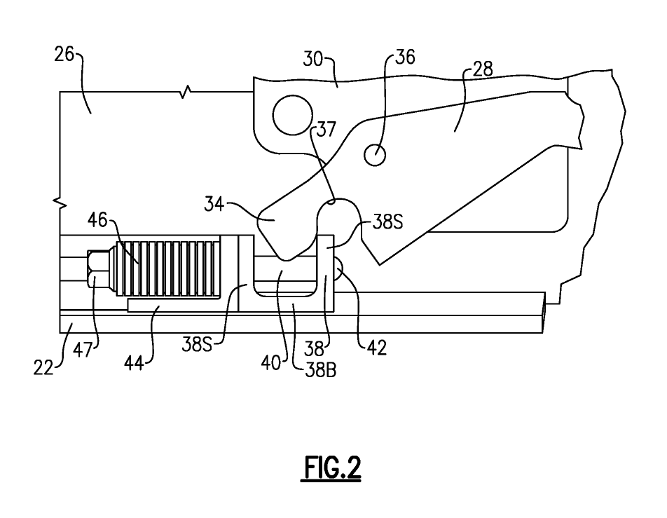

FIG. 2 shows the locking assembly in an unlocked position. The lever 28 is pivoted outwardly away from a lock bracket 38. Lock bracket 38 is u-shaped, with sides 38S and a bottom 38B to define the u-shape.

As can be seen, a holder, such as a bolt or pin 40 extends through the sides 38S of lock bracket 38 and provides an abutment for a Belleville washer set or a spring of sufficient force 46 that is mounted in a fixed bracket 44. Fixed bracket 44 is L-shaped. A nut 47 on holder 40 provides a stop. The bracket 44 is fixed on the chassis 22 while the lock bracket 38 is slidable along the chassis 22. A head 42 of the holder 40 is on an opposed side of the bracket 38. A head 34 of the lever 28 is illustrated along with a pivot pin 36. A channel 37 is intermediate the pivot pin 36 and the head 34.

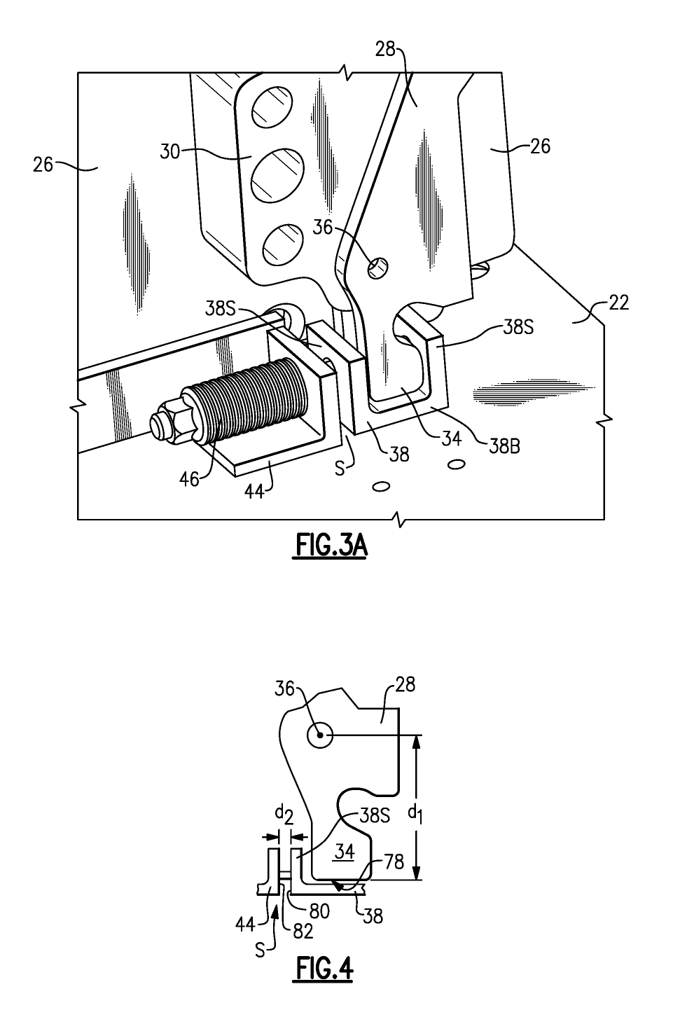

As shown in FIG. 3A, the lever 28 has now been pivoted to a locked position. The head 34 cams against side wall 38S on the lock bracket 38 to move the lock bracket in an outward direction. As can be seen, there is a space S between the brackets 44 and 38. That is, when the lever 28 is moved to this position, it pulls the lock bracket 38 away from the fixed bracket 44, and against the bias force of the Belleville washers 46. When the lever 28 is in this position, the spring pushes the bracket 30 and hence the LRM 26 further into the chassis, such that the connection 27 between the motherboard 24 and the LRM 26 is fully closed.

FIG. 3B shows a locking pawl 90 which is pivotally connected to the lever 28. Pawl 90 has arms 92 that can be pivoted to the position illustrated where they lock on pins 94 on the bracket 30. The pawl 90 is moved to this position once the lever has been moved to the FIG. 3A/3B position, and the pawl 90 locks the lever at that position.

To remove the LRM 26, the pawl 90 is pivoted away from the FIG. 3B position, releasing the lever. As can also be seen, the lever 28 has heads 34 spaced about a central member 96 of the bracket 30. Thus, the pin 40 can extend between the spaced heads 34.

In a method of installing a circuit board into a motherboard according to this disclosure, a circuit board 26 is initially moved into the chassis 22, and moved toward the motherboard 24 for connection. During this movement, it may be necessary to slightly pivot the levers 28 such that the head 34 can move beyond an outer side 38S of the lock bracket 38 at both of the two locations.

Once the circuit board 26 is moved into the chassis sufficiently such that the head 34 of the lever 28 can be moved between the side walls 38S of the lock bracket 38, the levers 28 are then pivoted to the position such as shown in FIG. 2.

Next, the levers 28 are pivoted such that the head 34 cams against the sides 38S on the lock brackets 38, and the levers are further pivoted, drawing the lock brackets 38 against the force from the spring 46 until it reaches the FIG. 3A position. In this position, the Belleville washers 46, or other bias members, pull the lock brackets 38 back into the chassis, thus causing the levers 28 to further pull the circuit board 26 into the chassis, ensuring an adequate connection. The pawl 90 is then moved to the FIG. 3B position.

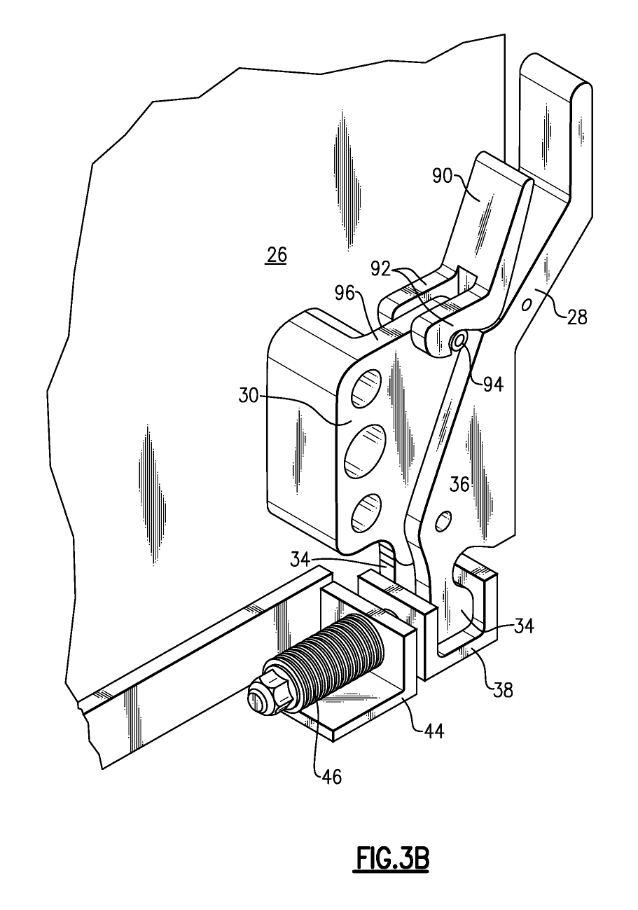

As shown in FIG. 4, a distance d₁ can be defined as between a center of the pivot point 36 and an end 78 on the head 34. A second distance d₂ is the distance across the gap S between the faces 82 and 80, respectively, of the brackets 44 and 38 ensures sufficient LRM movement to compensate for the tolerance accumulation of the system

In embodiments, d2 is a subset or partial part of the overall LRM travel that results from the d1 moment arm length and movement. The LRM 26 required overall movement or engagement travel will be vary depending on the mating connector types used between the LRM 26 and the motherboard, Item 24. Thus, d1 is selected to provide adequate LRM 26 movement to ensure a proper connection given the greatest possible tolerance stack-up for a given system.

In one feature, a chassis for a control module provides a housing having an inner end 25 and a forward opening 27. A fixed bracket 44 mounts a biasing member 46, and a lock bracket 38 slides on the housing. Lock bracket 38 is spaced towards the opening 27 from the fixed bracket 44. Biasing member 46 biases lock bracket 38 towards fixed bracket 44.

Although LRMs are disclosed, other circuit boards may come within the scope of this disclosure. In addition, while Belleville washers 46 are illustrated, other biasing members would come within the scope of this disclosure.

Although an embodiment of this invention has been disclosed, a worker of ordinary skill in this art would recognize that certain modifications would come within the scope of this invention. For that reason, the following claims should be studied to determine the true scope and content of this invention.

1. A control module comprising:
a motherboard; and
at least one circuit board removably connected to said motherboard, and there being at least one lever connected to said removable circuit board, and said lever being moveable between a release and a locked position, and said lever contacting a lock bracket in said locked position to move said bracket against a spring force, such that a bias force maintains said at least one circuit board in contact with said motherboard.

2. The control module as set forth in claim 1, wherein said lock bracket slides on a chassis, as said lever moves between said release and locked positions.

3. The control module as set forth in claim 2, wherein said lock bracket is moveable relative to a fixed bracket and said fixed bracket mounting a bias member biasing said lock bracket toward said motherboard, to provide said bias force.

4. The control module as set forth in claim 3, wherein said circuit board is generally planar and extends between two ends and there being levers and lock brackets at each of said two ends.

5. The control module as set forth in claim 4, wherein said at least one circuit board includes a plurality of removable circuit boards.

6. The control module as set forth in claim 4, wherein said lever is pivotally mounted on a bracket on a side of said at least one circuit board.

7. The control module as set forth in claim 4, wherein said lever has a head which cams against a side of said lock bracket when said lever is in said locked position.

8. The control module set forth in claim 7, wherein said lever has a pair of spaced heads which cam said side of said lock bracket when said lever is in said locked position.

9. The control module as set forth in claim 4, wherein said fixed bracket receives a holder for said biasing member that extends through said lock bracket.

10. The control module as set forth in claim 1, wherein said biasing member includes Belleville washers.

11. The control module as set forth in claim 1, wherein said lever has a head which cams a side of said lock bracket when said lever is in said locked position.

12. The control module set forth in claim 1, wherein a distance between a center of a pivot point on said lever and an outer end of a head on said lever is selected such that as said lever is moved to said locked position a resultant overall travel of said circuit board is adequate to ensure a proper connection given the greatest possible tolerance stack-up of the control module of the mother board and said removable circuit board.

13. The control module as set forth in claim 1, wherein said lock bracket is moveable relative to a fixed bracket and said stationary bracket mounting a bias member biasing said lock bracket toward said motherboard, to provide said bias force.

14. The control module as set forth in claim 1, wherein said circuit board is generally planar and extends between two ends and there being levers and lock brackets at each of said two ends.

15. The control module as set forth in claim 1, wherein said at least one circuit board includes a plurality of removable circuit boards.

16. The control module as set forth in claim 1, wherein said at least one removable circuit board is a line replaceable module.

17. A circuit board comprising:
a body configured to functionally attach to a motherboard positioned within a housing due to movement of said body; and
a lever pivotally connected to said body configured to move the body relative to the housing toward the motherboard when pivoted between a first position and a second position, a distance between a center of a pivot point on said lever and an outer end of a head on said lever being selected such that as said lever is moved from the first position to the second position the body moves toward the motherboard a dimension sufficient to ensure proper functional engagement between the circuit board and the motherboard at all possible tolerance stack-up conditions of the motherboard, the housing and the circuit board.

18. A chassis for a control module comprising:
a housing having an inner end and a forward opening;
a biasing member, and a lock bracket which slides on the housing, said biasing member biasing said lock bracket towards said inner end.

19. The chassis as set forth in claim 18, wherein a fixed bracket receives a holder for said biasing member that extends through said lock bracket.

20. The chassis as set forth in claim 19, wherein said biasing member includes Belleville washers.
